(19) United States
(12) Patent Application Publication
(10) Pub. No.: US 2026/0288000 A1
(43) Pub. Date: Sep. 24, 2026

(54) POSITIVE RESIST FOR DRY DEVELOPMENT, METHOD FOR MANUFACTURING SEMICONDUCTOR DEVICES USING THE SAME AND MULTILAYERED STRUCTURE FORMED USING THE SAME

(71) Applicants: Samsung Electronics Co., Ltd., Suwon-si (KR); Inha University Research and Business Foundation, Michuhol-gu (KR)

(72) Inventors: Sung Il Lee, Suwon-si (KR); Jin-Kyun Lee, Michuhol-gu (KR); Gayoung Kim, Michuhol-gu (KR); Jin Choi, Suwon-si (KR); Changyoung Jeong, Suwon-si (KR)

(21) Appl. No.: 19/570,830

(22) Filed: Mar. 18, 2026

(30) Foreign Application Priority Data
Mar. 19, 2025 (KR) 10-2025-0035616
Feb. 3, 2026 (KR) 10-2026-0021695

(51) Int. Cl. G03F 7/004; C08F 12/24; G03F 7/039; G03F 7/16; H10P 76/20

(52) U.S. Cl. CPC G03F 7/0043; C08F 12/24; G03F 7/039; G03F 7/168; H10P 76/2041

(57) ABSTRACT

A positive resist for dry development includes tin oxide nanoclusters, and a compound having Lewis basicity. The tin oxide nanoclusters includes a core structure having tin oxide. At least a portion of the tin oxide nanoclusters includes organic ligands bonded to the core structure. The organic ligands include alkyl groups having 1-20 carbon atoms bonded to a tin element in the core structure.

### CROSS-REFERENCE TO RELATED APPLICATIONS

This application claims priority to Korean Patent Application No. 10-2025-0035616, filed in the Korean Intellectual Property Office on Mar. 19, 2025, and Korean Patent Application No. 10-2026-0021695, filed in the Korean Intellectual Property Office on Feb. 3, 2026, the entire contents of which are hereby incorporated by reference.

### BACKGROUND

Photolithography may include an exposure process and a development process. Performing the exposure process may include irradiating a resist with light of a specific wavelength to induce a change in a chemical structure of the resist. Performing the development process may include selectively removing an exposed portion or an unexposed portion of the resist by using an etchability difference between the exposed portion and the unexposed portion of the resist.

As semiconductor devices have recently become highly integrated and miniaturized, line widths of patterns in the semiconductor devices are being miniaturized. To form fine patterns, various studies are being conducted to improve resolution and sensitivity of a resist pattern formed by photolithography.

When a wet development process is used among development processes, a capillary phenomenon may occur due to a developer used in the development process. Due to this, a problem may occur in which the resist pattern collapses in the wet development process, and in particular, there may be a limit to uniform formation of the resist pattern having an ultra-fine line width.

### SUMMARY

Implementation of the present disclosure relate to a positive resist for dry development, a method for manufacturing a semiconductor device using the same, and a multilayered structure formed using the same.

A technical object to be achieved by the present disclosure is to provide a metal oxide-based positive resist for dry development usable for ultraviolet and electron beam lithography.

Another technical object to be achieved by the present disclosure is to provide a method for manufacturing a semiconductor device using the positive resist for dry development, and a multilayered structure formed using the positive resist for dry development.

Objects to be achieved by the present disclosure are not limited to those mentioned above, and other objects not mentioned may be clearly understood by those skilled in the art from the description of the disclosure below.

A positive resist for dry development according to an implementation of the present disclosure includes tin oxide nanoclusters and a compound having Lewis basicity, and the tin oxide nanoclusters include a core structure including tin oxide.

A method for manufacturing a semiconductor device according to an implementation of the present disclosure includes forming an etch target layer on a substrate, forming a positive resist for dry development on the etch target layer, performing an exposure process on the positive resist for dry development, and performing a dry development process to selectively remove an exposure region of the positive resist for dry development, wherein the positive resist for dry development includes tin oxide nanoclusters and a compound having Lewis basicity, and the tin oxide nanoclusters include a core structure including tin oxide.

A multilayered structure according to an implementation of the present disclosure includes a substrate, an etch target layer disposed on the substrate, and a positive resist for dry development disposed on the etch target layer, wherein the positive resist for dry development includes tin oxide nanoclusters and a compound having Lewis basicity, and the tin oxide nanoclusters include a core structure including tin oxide.

According to some implementations of the present disclosure, the positive resist for dry development has high resolution and sensitivity for electron beam and ultraviolet lithography processes, and etch resistance of a non-exposure region forming a resist pattern may be increased compared to a polymer resist.

According to some implementations of the present disclosure, etchability with respect to a development gas is improved in the exposure region of the positive resist for dry development, so that an etch contrast between the exposure region and the non-exposure region of the positive resist for dry development may increase.

According to some implementations of the present disclosure, collapse of the resist pattern occurring due to a capillary phenomenon caused by a developer used in a wet development process is suppressed, and accordingly, a positive resist pattern having an ultra-fine line width may be uniformly formed.

### BRIEF DESCRIPTION OF THE DRAWINGS

FIG. 1 is an optical microscope image of a resist thin film formed by an ultraviolet lithography process according to Experimental Example 2.

FIG. 2 illustrates an optical microscope image and a scan image of a surface profiler of a resist thin film formed by an ultraviolet lithography process according to Experimental Example 3.

FIG. 3 illustrates an optical microscope image and a scan image of a surface profiler of a resist thin film formed by an ultraviolet lithography process according to Experimental Example 4.

FIG. 4 illustrates an optical microscope image and a scan image of a surface profiler of a resist thin film formed by an ultraviolet lithography process according to Experimental Example 5.

FIG. 5 illustrates an optical microscope image and a scan image of a surface profiler of a resist thin film formed by an ultraviolet lithography process according to Experimental Example 6.

FIG. 6 illustrates an optical microscope image and a scan image of a surface profiler of a resist thin film formed by an ultraviolet lithography process according to Experimental Example 7.

FIGS. 7-10 are diagrams illustrating a method for manufacturing a semiconductor device using a positive resist for dry development according to implementations of the present disclosure.

### DETAILED DESCRIPTION

In the present specification, an alkyl group includes a linear, branched, or cyclic monovalent saturated hydrocarbon group unless otherwise specified.

In the present specification, a hydrocarbon ring includes an aliphatic hydrocarbon ring and an aromatic hydrocarbon ring. The hydrocarbon ring may be monocyclic or polycyclic. The number of carbon atoms of the aromatic hydrocarbon ring is not particularly limited, but may be 6-30. In the present specification, an aromatic ring may include an aromatic hydrocarbon ring and an aromatic heterocycle. A heterocycle includes an aliphatic heterocycle and an aromatic heterocycle. The heterocycle may be monocyclic or polycyclic.

In the present specification, “substituted or unsubstituted” may mean being unsubstituted or substituted with one or more substituents, which may include one or more of a deuterium atom, a halogen atom, a hydroxyl group, an (e.g., C1-C20) alkoxy group, an (e.g., C1-C20) ether group, a (e.g., C1-C20) halogenated alkyl group, a (e.g., C1-C20) halogenated alkoxy group, a (e.g., C1-C20) halogenated ether group, an (e.g., C1-C20) alkyl group, an (e.g., C2-C20) alkenyl group, an (e.g., C6-C20) aryl group, a (e.g., C3-C30 or C3-C20) hydrocarbon ring group, or a (e.g., C2-C20) heterocyclic group. In addition, each of the substituents exemplified above may be substituted or unsubstituted. For example, a halogenated alkoxy group may be interpreted as an alkoxy group substituted with halogen.

In the present specification, unless otherwise defined, a case where a chemical bond is not drawn at a position where a chemical bond should be drawn may mean that a hydrogen atom is bonded at the position.

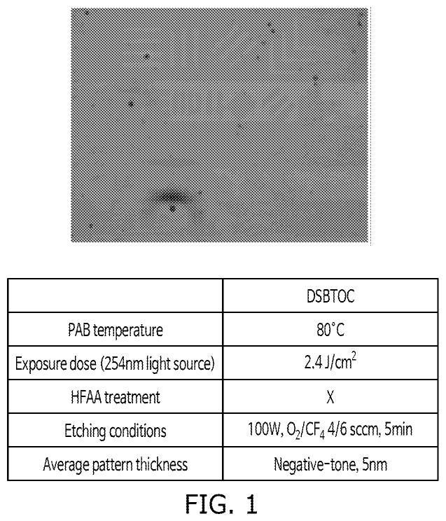

Hereinafter, various implementations of the present disclosure will be described with reference to FIGS. 1-10. The same reference numerals may refer to the same components throughout the entire specification.

A positive resist for dry development according to implementations of the present disclosure is described.

The positive resist for dry development according to the implementations of the present disclosure may be used for manufacturing a semiconductor device and may be used for a photolithography process for manufacturing a semiconductor device. The positive resist for dry development may be used for, for example, an ultraviolet or electron beam (e-beam) lithography process. Ultraviolet rays may be, for example, extreme ultraviolet ray (EUV) or deep ultraviolet ray (DUV). A light source used in the extreme ultraviolet lithography process may have a wavelength of, for example, 10 nm-124 nm. A light source used in the deep ultraviolet lithography process may have a wavelength of, for example, 180 nm-280 nm.

The positive resist for dry development according to the present disclosure is used in a sense encompassing both a resist before exposure and a resist after exposure.

Unlike a resist for wet development which depends on a solubility difference, the positive resist for dry development according to the present disclosure is based on a mechanism for suppressing aggregation between cores in an exposure region and controlling sublimation of a complex compound. Tin oxide nanoclusters alone enhance etch resistance due to strong aggregation between Lewis acidic cores during exposure, thereby forming a negative pattern. On the other hand, when the tin oxide nanoclusters and a Lewis basic compound are mixed as in the implementation of the present disclosure, Lewis acidic sites generated in the exposure region and Lewis basic functional groups preferentially bond to block aggregation between the cores. The exposure region comes to have a significantly higher etch rate compared to a non-exposure region when exposed to a dry development gas (e.g., hexafluoroacetylacetone (HFAA), etc.), which blocks pattern collapse occurring in wet development and enables realization of an ultra-fine line width.

The positive resist for dry development according to an implementation of the present disclosure may be formed from a positive resist composition for dry development. The positive resist composition for dry development may be a mixed composition including tin oxide nanoclusters and a compound having Lewis basicity. The tin oxide nanoclusters in the positive resist composition for dry development may include a core structure including tin oxide and organic ligands bonded to the core structure. In an implementation, the tin oxide nanoclusters may not include a counter anion. For example, the core structure in the tin oxide nanoclusters may be electrically neutral and may exist in a state not bonded to a counter anion. In another implementation, the tin oxide nanoclusters may further include counter anions bonded to the core structure. For example, the core structure may be positively charged and exist in a state bonded to the counter anions.

Hereinafter, for convenience of explanation, a description will focus on a case where the core structure in the tin oxide nanocluster is positively charged and in a state bonded to the counter anions.

In an embodiment, the tin oxide nanoclusters in the positive resist composition for dry development may include 4-30, for example, 5-25, 6-20, 7-15 or 8-12 tin atoms and oxygen atoms bonded to these tin atoms. In the tin oxide nanoclusters, one tin atom may be bonded to, for example, 3-4 (e.g. 4) oxygen atoms, and one oxygen atom may be bonded to 2-3 (e.g., 3) tin atoms. The tin oxide nanoclusters may further include an organic ligand which is bonded to at least a portion (e.g., all) of the tin atoms. The organic ligand may be, for example, an alkyl group having 1-20 carbon atoms. The tin oxide nanoclusters may further include at least one of a sulfonate anion or a carboxylate anion bonded to the core structure as a counter anion.

In an implementation, the tin oxide nanoclusters in the positive resist composition for dry development may be represented by Chemical Formula 1 below.

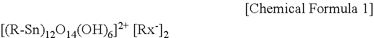

In Chemical Formula 1, R is an organic ligand, and Rx⁻ is a counter anion.

In an implementation, the organic ligand R may be an alkyl group having 1-20 carbon atoms bonded to a tin element in the core structure.

In an implementation, the counter anion Rx⁻ may include at least one of a sulfonate anion or a carboxylate anion bonded to the core structure. The carboxylate anion included as the counter anion Rx may include, for example, at least one of a pentanoate anion, a pentenoate anion, a methacrylate anion, a benzoate anion, a p-toluate anion, an acetate anion, an isobutyrate anion, or a malonate anion. The sulfonate anion included as the counter anion Rx⁻ may include, for example, at least one of a benzene sulfonate anion, a methane sulfonate anion, or a camphor-10-sulfonate anion. The benzene sulfonate anion may be substituted or unsubstituted, for example, it may be substituted with one or more alkyl groups having 1-20 carbon atoms.

In an implementation, the counter anion Rx may be an alkyl benzene sulfonate anion and may be represented by Structural Formula 1 below.

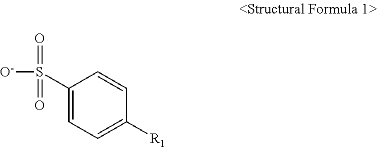

In Structural Formula 1, R₁ is an alkyl group having 1-20 carbon atoms.

The tin oxide nanoclusters in the positive resist composition for dry development represented by Chemical Formula 1 may include a material represented by Structural Formula 2 below.

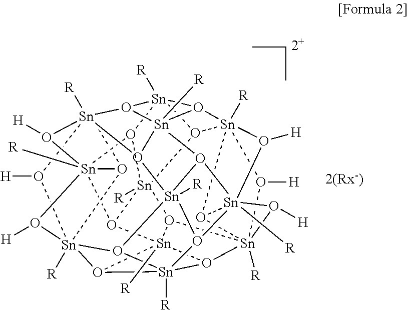

In Structural Formula 2, R is a butyl group, and Rx⁻ is a counter anion represented by Structural Formula 3 below.

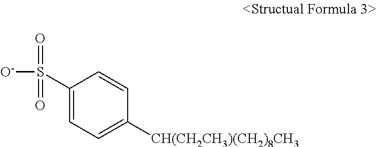

The compound having Lewis basicity in the positive resist composition for dry development may include at least one of a polymer or an organic small molecule having a functional group that acts as a Lewis base. The functional group that acts as a Lewis base may have a lone pair of electrons. The functional group that acts as a Lewis base may include, for example, at least one of a hydroxyl group, a phenol group, a thiol group, an amine group, a carboxylic acid group, an ester group, a carbonyl group, an amide group, a carbamate group, an urea group, a sulfoxy group, a sulfonyl group, a sulfone ester group, a cyanide group, or an isocyanide group.

In an implementation, the compound having Lewis basicity may include a polymer having a phenol group as the functional group that acts as a Lewis base. The polymer having a phenol group may include, for example, a repeating unit represented by Structural Formula 4 below.

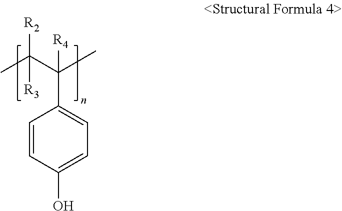

In Structural Formula 4, R₂, R₃, and R₄ are each independently hydrogen, deuterium, or an alkyl group having 1-10 carbon atoms, and n is an integer in a range of from 1 to 1000.

The polymer having a phenol group may include, for example, a copolymer represented by Structural Formula 5 below.

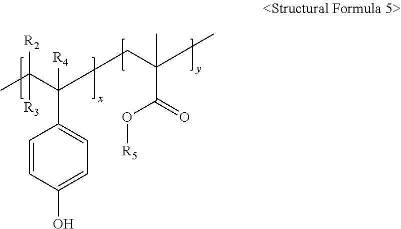

In Structural Formula 5, R₂, R₃, and R₄ are each independently hydrogen, deuterium, or an alkyl group having 1-10 carbon atoms, R₅ is hydrogen, deuterium, an alkyl group having 1-10 carbon atoms, or a substituted or unsubstituted hydrocarbon ring having 3-30 carbon atoms, x is an integer in a range of from 1 and 1000, and y is an integer in a range of from 1 and 1000.

In an implementation, the compound having Lewis basicity may include an organic small molecule having a phenol group as the functional group that acts as a Lewis base. The organic small molecule having a phenol group may include, for example, at least one of compounds represented by Structural Formula 6, Structural Formula 7, or Structural Formula 8 below.

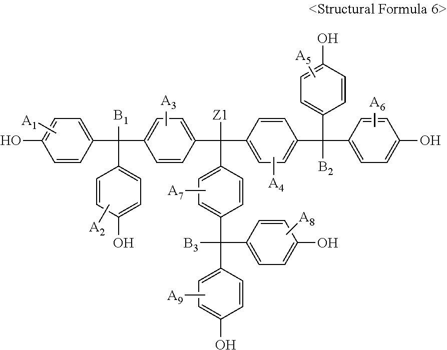

In Structural Formula 6, A₁, A₂, A₃, A₄, A₅, A₆, A₇, A₈, and A₉ are each independently hydrogen, deuterium, or an alkyl group having 1-10 carbon atoms, B₁, B₂, and B₃ are each independently hydrogen, deuterium, or an alkyl group having 1-10 carbon atoms, and Z₁ is hydrogen, deuterium, an alkyl group having 1-10 carbon atoms, or a substituted or unsubstituted hydrocarbon ring having 3-30 carbon atoms. It will be understood that in Structural Formula 6, the number of each of A₁, A₂, A₃, A₄, A₅, A₆, A₇, As, and A₉ may be independently an integer in a range of from 1 to m, wherein m is the number of substitutable sites of the corresponding benzene ring. For example, the number of A₁ may be 1 to 4. Such understanding may also be applicable to other Structural Formulae such as Structural Formulae 7 and 8 herein.

In an implementation, the organic small molecule represented by Structural Formula 6 may include a material represented by Structural Formula 6A below.

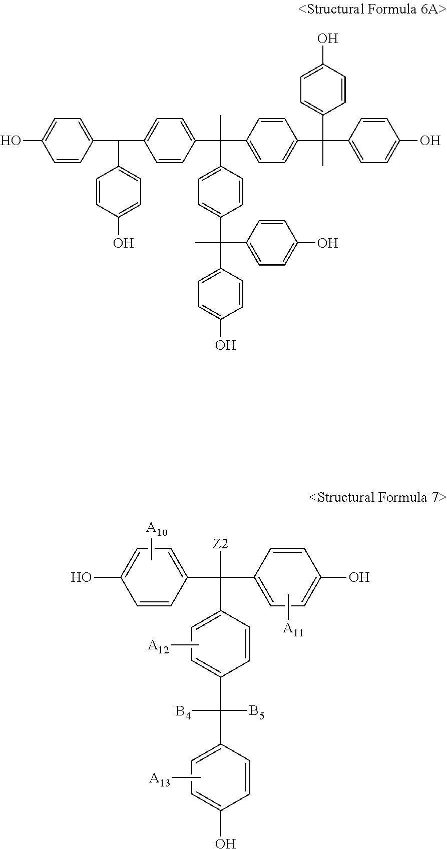

In Structural Formula 7, A₁₀, A₁₁, A₁₂, and A₁₃ are each independently hydrogen, deuterium, or an alkyl group having 1-10 carbon atoms, B₄ and B₅ are each independently hydrogen, deuterium, or an alkyl group having 1-10 carbon atoms, and Z₂ is hydrogen, deuterium, an alkyl group having 1-10 carbon atoms, or a substituted or unsubstituted hydrocarbon ring having 3-30 carbon atoms.

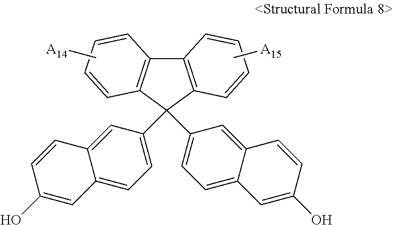

In Structural Formula 8, A₁₄ and A₁₅ are each independently hydrogen, deuterium, an alkyl group having 1-10 carbon atoms, or a substituted or unsubstituted hydrocarbon ring having 3-30 carbon atoms.

In an implementation, the compound having Lewis basicity may include an organic small molecule having an ester group as the functional group that acts as a Lewis base. The organic small molecule having an ester group may be, for example, a tannic acid-based compound, and may be represented by Structural Formula 9 below.

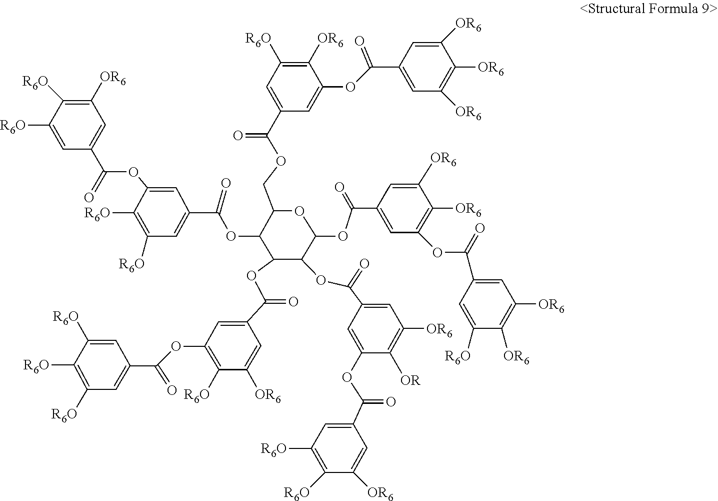

In Structural Formula 9, R₆ may be represented by Structural Formula 10 below.

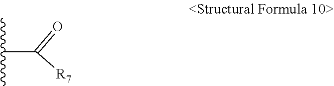

In Structural Formula 10, R₇ is hydrogen, deuterium, an alkyl group having 1-10 carbon atoms, or a substituted or unsubstituted hydrocarbon ring having 3-30 carbon atoms.

In an embodiment, in the positive resist for dry development or the positive resist composition for dry development, the weight ratio of the tin oxide nanoclusters to the compound having Lewis basicity is not particularly limited, but may be in a range of 1:0.02 to 1:0.8, for example, 1:0.04 to 1:0.6, 1:0.06 to 1:0.4, 1:0.08 to 1:0.2, 1:0.09 to 1:0.18, or 1:0.10 to 1:0.16.

A positive resist for dry development according to an implementation may be formed from the positive resist composition for dry development described above. In the present disclosure, the positive resist for dry development may mean a resist thin film capable of forming a positive pattern by a dry development process. The positive resist for dry development formed from the positive resist composition for dry development described above includes tin oxide nanoclusters and a compound having Lewis basicity, and the tin oxide nanoclusters may include a core structure including tin oxide. In an implementation, the tin oxide nanoclusters may further include counter anions bonded to the core structure. Regarding the compound having Lewis basicity and the counter anions bonded to the core structure, the description regarding the positive resist composition for dry development described above may be identically applied. However, as described above, the core structure may be electrically neutral and exist in a state not bonded to the counter anions.

In the present disclosure, the positive resist for dry development may be used in a sense encompassing a resist thin film before a later-described exposure process is performed, a resist thin film after the exposure process is performed, or both. For example, the positive resist for dry development is a resist thin film before the exposure process is performed, and the entire resist thin film may be a non-exposure region. For example, the positive resist for dry development is a resist thin film after the exposure process is performed, at least a portion of the resist thin film is an exposure region exposed to light, and the remaining portion may be a non-exposure region not exposed to light.

Tin oxide nanoclusters in the positive resist for dry development before performing the exposure process may include organic ligands bonded to a core structure including tin oxide. The positive resist for dry development before performing the exposure process may have the same composition as the positive resist composition for dry development described above. For example, the tin oxide nanoclusters in the positive resist for dry development before performing the exposure process are represented by Chemical Formula 1, and the tin oxide nanoclusters in the positive resist for dry development before performing the exposure process represented by Chemical Formula 1 may include the material represented by Structural Formula 2.

The positive resist for dry development before performing the exposure process is a mixture of tin oxide nanoclusters and a compound having Lewis basicity, and the tin oxide nanoclusters may include a core structure including tin oxide and organic ligands bonded to the core structure. Regarding the organic ligands, the description regarding the organic ligands described above for the positive resist composition for dry development may be identically applied.

The positive resist for dry development after performing the exposure process may include an exposure region exposed to light. For example, the positive resist for dry development may include an exposure region exposed by light and a non-exposure region not exposed to light.

The non-exposure region of the positive resist for dry development may have the same composition as the positive resist for dry development before performing the exposure process described above. For example, after performing the exposure process, the non-exposure region of the positive resist for dry development includes a mixture of tin oxide nanoclusters and a compound having Lewis basicity, and the tin oxide nanoclusters may include a core structure including tin oxide and organic ligands bonded to the core structure.

At least a portion of the tin oxide nanoclusters located in the exposure region of the positive resist for dry development may include a compound having Lewis basicity bonded to the core structure including tin oxide. The compound having Lewis basicity bonded to the core structure may be the same material as the compound having Lewis basicity in the positive resist composition for dry development.

When the positive resist for dry development before performing the exposure process described above is irradiated with an electron beam or ultraviolet rays, the organic ligand R may be detached from the tin oxide nanoclusters in the positive resist for dry development before performing the exposure process represented by Chemical Formula 1 by electron beam or ultraviolet photons. For example, the organic ligand R bonded to the core structure of the tin oxide nanocluster is detached by the electron beam or ultraviolet photons, and accordingly, the core structure of the tin oxide nanocluster may have Lewis acidity. As the compound having Lewis basicity described above bonds to the core structure of the tin oxide nanocluster having Lewis acidity due to the detachment of the organic ligand through a functional group having Lewis basicity, aggregation between the core structures having Lewis acidity may be suppressed. Accordingly, the tin oxide nanoclusters whose aggregation is suppressed may be selectively removed by a development gas in a later-described dry development process.

In an implementation, after performing the exposure process on the positive resist for dry development, the positive resist for dry development may be treated with an electron-donating ligand. Due to treatment with the electron-donating ligand, at least a portion of the tin oxide nanoclusters in the exposure region of the positive resist for dry development may include an electron-donating ligand bonded to the core structure including tin oxide.

The electron-donating ligand may bond with the tin oxide nanoclusters in the exposure region having Lewis acidity due to the detachment of the organic ligands. For example, at least a portion of the tin oxide nanoclusters in the exposure region bonds with the compound having Lewis basicity so that mutual aggregation is suppressed, and the electron-donating ligand may bond to the core structure having Lewis acidity in the tin oxide nanoclusters whose aggregation is suppressed. The electron-donating ligand may be a ligand that bonds to the core structure having Lewis acidity to form a volatile metal compound. Accordingly, etchability of the exposure region by a dry development gas may be further improved thereafter.

The electron-donating ligand may include at least one of an amine-based ligand or an oxygen-based ligand. The amine-based electron-donating ligand may be represented by, for example, Structural Formula 11A, 11B, 11C, 11D, 11E, or 11F below.

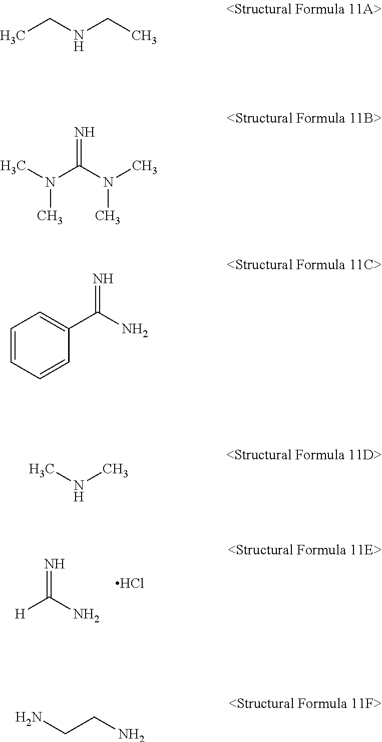

The oxygen-based electron-donating ligand may be, for example, hexafluoroacetylacetone (HFAA) represented by Structural Formula 11G below.

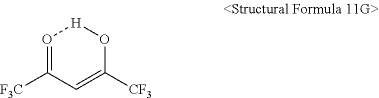

However, the electron-donating ligand applicable to the present disclosure is not limited to the compounds represented by Structural Formulas 11A-11G described above, and any compound used in the relevant technical field to improve sublimation of a resist thin film for dry development may be applied without limitation.

When a ligand containing fluorine, for example, the ligand represented by Structural Formula 11G, is used as the electron-donating ligand, sublimation of the tin oxide nanoclusters bonded with the electron-donating ligand may be further improved. For example, as the ligand containing fluorine bonds with at least a portion of the tin oxide nanoclusters in the exposure region, fluorine is introduced into the tin oxide nanoclusters, and accordingly, etchability by the dry development gas is further improved, so that an etch contrast between the exposure region and the non-exposure region may be maximized.

The positive resist for dry development according to the present disclosure may be a non-chemically amplified positive resist. As the resist includes tin oxide nanoclusters, it may have high resolution and sensitivity for electron beam and ultraviolet lithography processes. In addition, as the resist includes tin oxide nanoclusters, etch resistance of the non-exposure region forming the resist pattern may increase. As the resist further includes a compound having Lewis basicity, the resist may have a required degree of etchability with respect to the dry development gas after being irradiated with an electron beam or ultraviolet rays. Accordingly, the exposure region of the resist may be removed by the dry development gas, and an etch contrast between the exposure region and the non-exposure region of the resist may increase.

### [Experimental Example 1] Synthesis of Tin Oxide Nanocluster Having Dodecylbenzenesulfonate as a Counter Anion (DSBTOC, Structural Formula 2) (Reaction Scheme 1)

A basic solution was prepared by adding TMAH (Tetramethylammonium Hydroxide) pentahydrate (5.78 g, 31.9 mmol) and deionized water (DI water, 64 cm³) into a vial, and then BuSnCl₃ (3.0 g, 10.6 mmol) was added. After the reactants were vigorously stirred at room temperature for 1 hour, the obtained product was filtered while being washed several times with DI water, and then recovered. After vacuum drying, a tin oxide cluster (BTOC, 2.2 g) in the form of a white solid was obtained. The synthesized BTOC was dissolved in 14.6 cm³ of Isopropanol and then purified through recrystallization to obtain needle-shaped BTOC (1.19 g). The purified BTOC (0.5 g, 0.20 mmol) was dissolved in tetrahydrofuran (THF, 4 cm³), and dodecylbenzenesulfonic acid (0.13 g, 0.40 mmol) was added. The reaction solution was stirred at 50° C. for 40 minutes, concentrated under reduced pressure, and dried to obtain DSBTOC (0.6 g) as a white solid.

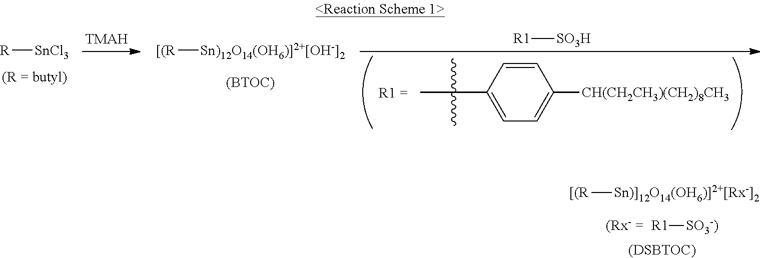

### [Experimental Example 2] Ultraviolet Lithography Evaluation for DSBTOC (Structural Formula 2) Resist Under a 254 nm Light Source

A resist composition solution with a concentration of 2.5 wt/vol % was prepared by dissolving DSBTOC in a mixed solvent of nBA (n-butyl acetate) and MEK (methyl ethyl ketone) in a volume ratio of 1:1. After spin coating the resist composition solution on a Si wafer at 2000 rpm for 60 seconds, PAB (post-apply baking) was performed at 80 degrees Celsius for 1 minute to form a resist thin film having a thickness of about 100 nm. The resist thin film was irradiated with ultraviolet rays from a 254 nm light source at 2.4 J/cm². Thereafter, dry development (etching) was performed for 5 minutes under a condition of 100 W and an O₂/CF₄4/6 sccm mixed gas in a reactive ion etching (RIE) method to form a pattern.

FIG. 1 is an optical microscope image of a resist thin film formed by an ultraviolet lithography process according to Experimental Example 2.

Referring to FIG. 1, it may be confirmed that a negative pattern having a thickness of 5 nm was formed on the resist thin film. As ultraviolet rays are irradiated on the resist thin film, organic ligands (butyl groups) of the tin oxide nanoclusters (DSBTOC) are detached in the exposure region of the resist thin film, and accordingly, the tin oxide nanoclusters (DSBTOC) may have strong Lewis acidity. Since the resist thin film in Experimental Example 2 does not include a compound having Lewis basicity, the tin oxide nanoclusters in the exposure region having Lewis acidity after exposure may aggregate with each other. Accordingly, etch resistance of the exposure region with respect to the dry development gas is improved so that the non-exposure region is preferentially etched, whereby a negative pattern may be formed.

### [Experimental Example 3] Ultraviolet Lithography Evaluation for DSBTOC (Structural Formula 2) Resist Under a 254 nm Light Source

A resist composition solution with a concentration of 2.5 wt/vol % was prepared by dissolving DSBTOC in a mixed solvent of nBA (n-butyl acetate) and MEK (methyl ethyl ketone) in a volume ratio of 1:1. After spin coating the resist composition solution on a Si wafer at 2000 rpm for 60 seconds, PAB (post-apply baking) was performed at 100 degrees Celsius for 1 minute to form a resist thin film having a thickness of about 100 nm. After the resist thin film was irradiated with ultraviolet rays from a 254 nm light source at 2.4 J/cm², HFAA (hexafluoroacetylacetone) treatment was performed at room temperature for 2 minutes. Thereafter, dry development (etching) was performed for 4 minutes and 30 seconds under a condition of 100 W and an O₂/CF₄ 4/6 sccm mixed gas in a reactive ion etching (RIE) method to form a pattern.

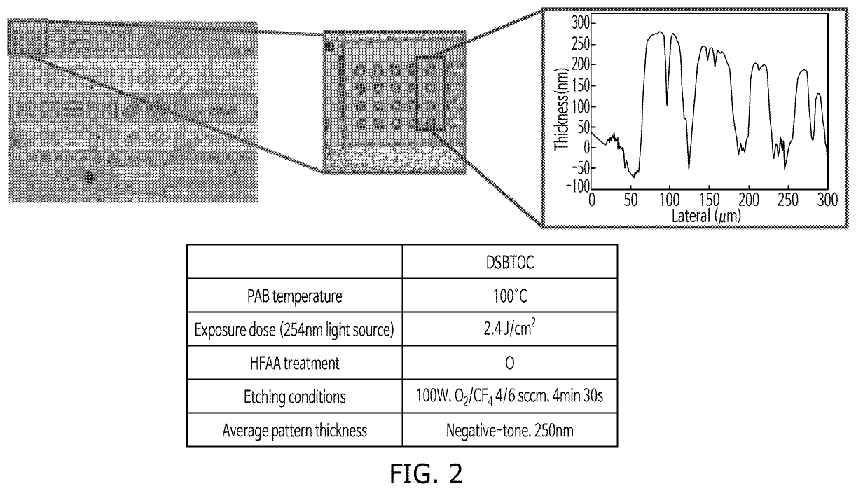

FIG. 2 illustrates an optical microscope image and a scan image of a surface profiler of a resist thin film formed by an ultraviolet lithography process according to Experimental Example 3.

Referring to FIG. 2, the thickness of the resist thin film was measured using a surface profiler, and it may be confirmed that a negative pattern having a thickness of 250 nm was formed on the resist thin film. As ultraviolet rays are irradiated on the resist thin film, organic ligands (butyl groups) of the tin oxide nanoclusters (DSBTOC) are detached in the exposure region of the resist thin film, and accordingly, the tin oxide nanoclusters (DSBTOC) may have strong Lewis acidity. Since the resist thin film in Experimental Example 3 does not include a compound having Lewis basicity, the tin oxide nanoclusters in the exposure region having Lewis acidity after exposure may aggregate with each other. Accordingly, etch resistance of the exposure region with respect to the dry development gas is improved so that the non-exposure region is preferentially etched, whereby a negative pattern may be formed.

### [Experimental Example 4] Ultraviolet Lithography Evaluation for DSBTOC (Structural Formula 2) Resist Under a 254 nm Light Source

A resist composition solution with a concentration of 2.5 wt/vol % was prepared by dissolving DSBTOC in a mixed solvent of nBA (n-butyl acetate) and MEK (methyl ethyl ketone) in a volume ratio of 1:1. After spin coating the resist composition solution on a Si wafer at 2000 rpm for 60 seconds, PAB (post-apply baking) was performed at 120 degrees Celsius for 1 minute to form a resist thin film having a thickness of about 100 nm. After the resist thin film was irradiated with ultraviolet rays from a 254 nm light source at 2.4 J/cm², HFAA (hexafluoroacetylacetone) treatment was performed at room temperature for 2 minutes. Thereafter, dry development (etching) was performed for 6 minutes and 30 seconds under a condition of 100 W and an O₂/CF₄ 4/6 sccm mixed gas in a reactive ion etching (RIE) method to form a pattern.

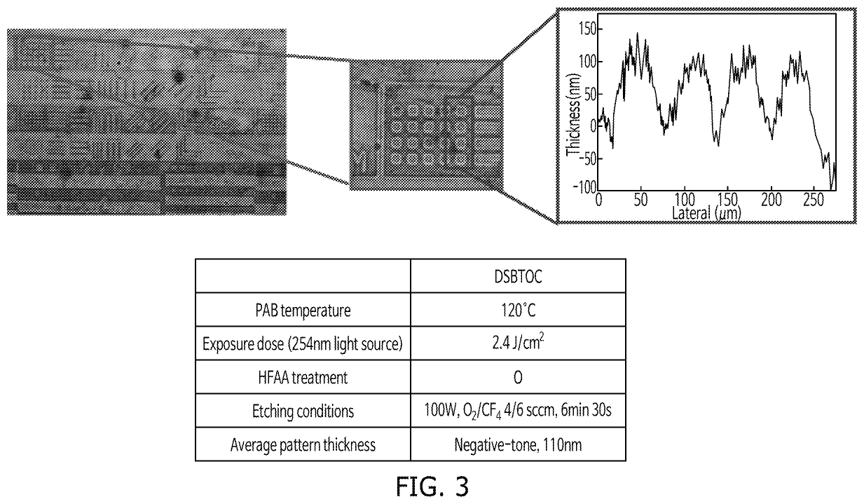

FIG. 3 illustrates an optical microscope image and a scan image of a surface profiler of a resist thin film formed by an ultraviolet lithography process according to Experimental Example 4.

Referring to FIG. 3, the thickness of the resist thin film was measured using a surface profiler, and it may be confirmed that a negative pattern having a thickness of 110 nm was formed on the resist thin film. As ultraviolet rays are irradiated on the resist thin film, organic ligands (butyl groups) of the tin oxide nanoclusters (DSBTOC) are detached in the exposure region of the resist thin film, and accordingly, the tin oxide nanoclusters (DSBTOC) may have strong Lewis acidity. Since the resist thin film in Experimental Example 4 does not include a compound having Lewis basicity, the tin oxide nanoclusters in the exposure region having Lewis acidity after exposure may aggregate with each other. Accordingly, etch resistance of the exposure region with respect to the dry development gas is improved so that the non-exposure region is preferentially etched, whereby a negative pattern may be formed.

### [Experimental Example 5] Ultraviolet Lithography Evaluation for Mixed Resist of DSBTOC (Structural Formula 2) and DHP (Structural Formula 6A) Under a 254 nm Light Source

A resist composition solution with a concentration of 2.5 wt/vol % was prepared by dissolving a mixture (weight ratio 1:0.1) of DSBTOC and DHP (4,4′,4″,4′″,4″″,4′″″-[[ethane-1,1,1-triyltris(benzene-4,1-diyl)]tris(ethane-1,1,1-triyl)]hexaphenol) in a mixed solvent of nBA (n-butyl acetate) and MEK (methyl ethyl ketone) in a volume ratio of 1:1. After spin coating the resist composition solution on a Si wafer at 2000 rpm for 60 seconds, PAB (post-apply baking) was performed at 100 degrees Celsius for 1 minute to form a resist thin film having a thickness of about 100 nm. The resist thin film was irradiated with ultraviolet rays from a 254 nm light source at 2.4 J/cm². Thereafter, dry development (etching) was performed for 5 minutes under a condition of 100 W and an O₂/CF₄ 4/6 sccm mixed gas in a reactive ion etching (RIE) method to form a pattern.

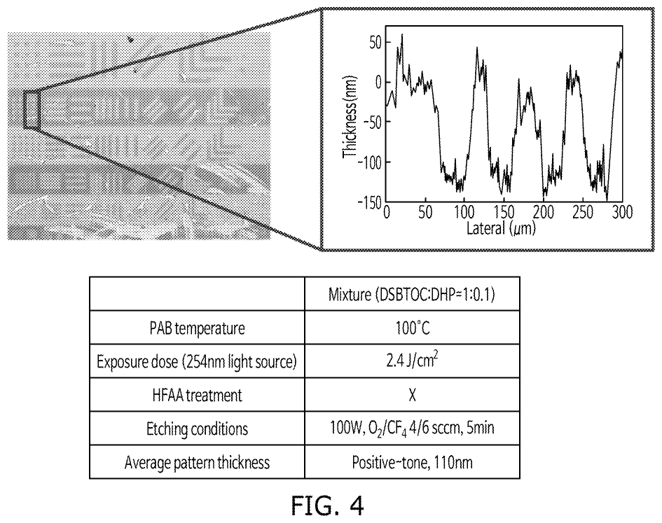

FIG. 4 illustrates an optical microscope image and a scan image of a surface profiler of a resist thin film formed by an ultraviolet lithography process according to Experimental Example 5.

Referring to FIG. 4, the thickness of the resist thin film was measured using a surface profiler, and it may be confirmed that a positive pattern having a thickness of 110 nm was formed on the resist thin film. As ultraviolet rays are irradiated on the resist thin film, organic ligands (butyl groups) of the tin oxide nanoclusters (DSBTOC) are detached in the exposure region of the resist thin film, and accordingly, the tin oxide nanoclusters (DSBTOC) may have strong Lewis acidity. The resist thin film in Experimental Example 5 includes a compound having Lewis basicity (DHP), and as the compound having Lewis basicity (DHP) bonds to the core structure of the tin oxide nanoclusters having Lewis acidity in the exposure region, aggregation between the tin oxide nanoclusters may be suppressed. Accordingly, etchability of the exposure region with respect to the dry development gas may be controlled, and an etch contrast between the exposure region and the non-exposure region may increase. Thereafter, the exposure region of the resist thin film is selectively removed by a dry development process using a dry development gas, so that a positive resist pattern may be formed.

### [Experimental Example 6] Ultraviolet Lithography Evaluation for Mixed Resist of DSBTOC (Structural Formula 2) and DHP (Structural Formula 6A) Under a 254 nm Light Source

A resist composition solution with a concentration of 2.5 wt/vol % was prepared by dissolving a mixture (weight ratio 1:0.1) of DSBTOC and DHP in a mixed solvent of nBA (n-butyl acetate) and MEK (methyl ethyl ketone) in a volume ratio of 1:1. After spin coating the resist composition solution on a Si wafer at 2000 rpm for 60 seconds, PAB (post-apply baking) was performed at 80 degrees Celsius for 1 minute to form a resist thin film having a thickness of about 100 nm. After the resist thin film was irradiated with ultraviolet rays from a 254 nm light source at 2.4 J/cm², HFAA (hexafluoroacetylacetone) treatment was performed at room temperature for 2 minutes. Thereafter, dry development (etching) was performed for 4 minutes and 30 seconds under a condition of 100 W and an O₂/CF₄ 4/6 sccm mixed gas in a reactive ion etching (RIE) method to form a pattern.

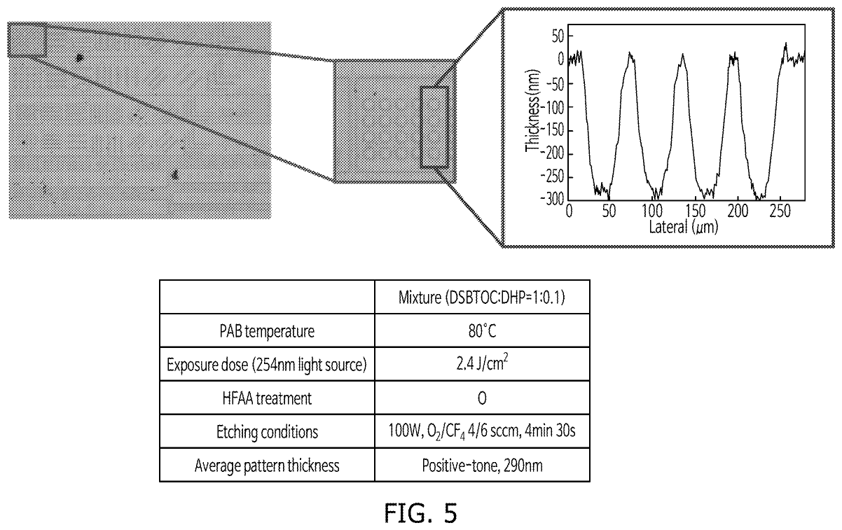

FIG. 5 illustrates an optical microscope image and a scan image of a surface profiler of a resist thin film formed by an ultraviolet lithography process according to Experimental Example 6.

Referring to FIG. 5, the thickness of the resist thin film was measured using a surface profiler, and it may be confirmed that a positive pattern having a thickness of 290 nm was formed on the resist thin film. As ultraviolet rays are irradiated on the resist thin film, organic ligands (butyl groups) of the tin oxide nanoclusters (DSBTOC) are detached in the exposure region of the resist thin film, and accordingly, the tin oxide nanoclusters (DSBTOC) may have strong Lewis acidity. The resist thin film in Experimental Example 6 includes a compound having Lewis basicity (DHP), and as the compound having Lewis basicity (DHP) bonds to the core structure of the tin oxide nanoclusters having Lewis acidity in the exposure region, aggregation between the tin oxide nanoclusters may be suppressed. Accordingly, etchability of the exposure region of the resist thin film with respect to the dry development gas may be controlled, and an etch contrast between the exposure region and the non-exposure region may increase. Thereafter, the exposure region of the resist thin film is selectively removed by a dry development process using a dry development gas, so that a positive resist pattern may be formed.

By treating with HFAA after forming the resist thin film, HFAA may bond to the tin oxide nanoclusters having Lewis acidity in the exposure region to form a volatile metal compound. Accordingly, the etch contrast between the exposure region and the non-exposure region further increases, so that the thickness of the resist pattern may increase compared to that shown in FIG. 4.

### [Experimental Example 7] Ultraviolet Lithography Evaluation for Mixed Resist of DSBTOC (Structural Formula 2) and DHP (Structural Formula 6A) Under a 254 nm Light Source

A resist composition solution with a concentration of 2.5 wt/vol % was prepared by dissolving a mixture (weight ratio 1:0.1) of DSBTOC and DHP in a mixed solvent of nBA (n-butyl acetate) and MEK (methyl ethyl ketone) in a volume ratio of 1:1. After spin coating the resist composition solution on a Si wafer at 2000 rpm for 60 seconds, PAB (post-apply baking) was performed at 120 degrees Celsius for 1 minute to form a resist thin film having a thickness of about 100 nm. After the resist thin film was irradiated with ultraviolet rays from a 254 nm light source at 2.4 J/cm², HFAA (hexafluoroacetylacetone) treatment was performed at room temperature for 2 minutes. Thereafter, dry development (etching) was performed for 7 minutes under a condition of 100 W and an O₂/CF₄ 4/6 sccm mixed gas in a reactive ion etching (RIE) method to form a pattern.

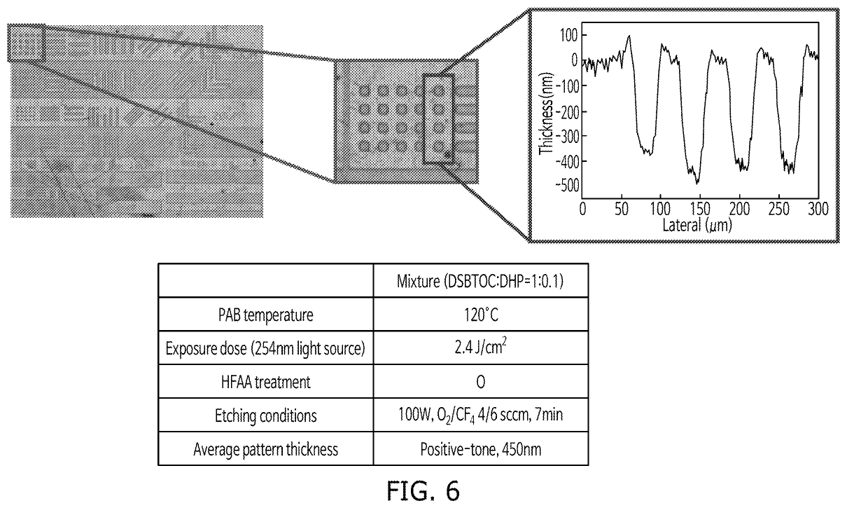

FIG. 6 illustrates an optical microscope image and a scan image of a surface profiler of a resist thin film formed by an ultraviolet lithography process according to Experimental Example 7.

Referring to FIG. 6, the thickness of the resist thin film was measured using a surface profiler, and it may be confirmed that a positive pattern having a thickness of 450 nm was formed on the resist thin film. As ultraviolet rays are irradiated on the resist thin film, organic ligands (butyl groups) of the tin oxide nanoclusters (DSBTOC) are detached in the exposure region of the resist thin film, and accordingly, the tin oxide nanoclusters (DSBTOC) may have strong Lewis acidity. The resist thin film in Experimental Example 7 includes a compound having Lewis basicity (DHP), and as the compound having Lewis basicity (DHP) bonds to the core structure of the tin oxide nanoclusters having Lewis acidity in the exposure region, aggregation between the tin oxide nanoclusters may be suppressed. Accordingly, etchability of the exposure region of the resist thin film with respect to the dry development gas may be controlled, and an etch contrast between the exposure region and the non-exposure region may increase. Thereafter, the exposure region of the resist thin film is selectively removed by a dry development process using a dry development gas, so that a positive resist pattern may be formed.

By treating with HFAA after forming the resist thin film, HFAA may bond to the tin oxide nanoclusters having Lewis acidity in the exposure region to form a volatile metal compound. Accordingly, the etch contrast between the exposure region and the non-exposure region further increases, so that the thickness of the resist pattern may increase compared to that shown in FIG. 4.

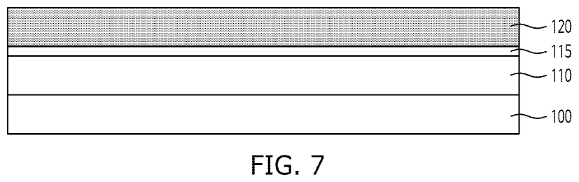

FIGS. 7-10 are diagrams illustrating a method for manufacturing a semiconductor device using a positive resist for dry development according to implementations of the present disclosure.

Referring to FIG. 7, the method for manufacturing a semiconductor device may include forming an etch target layer 110 on a substrate 100, and forming a positive resist for dry development 120 on the etch target layer 110. In an implementation, an underlayer 115 may be disposed between the etch target layer 110 and the positive resist for dry development 120. The substrate 100 may be a semiconductor substrate, and for example, may be a silicon substrate, a germanium substrate, or a silicon/germanium substrate. As another example, the substrate 100 may be a metal substrate such as Cr substrate or Ta substrate. The etch target layer 110 may be made of any one selected from a semiconductor material, a conductive material, and an insulating material, or a combination thereof. The etch target layer 110 may be formed as a single layer or may include a plurality of layers stacked on the substrate 100.

The underlayer 115 may be formed between the etch target layer 110 and the positive resist for dry development 120 and may easily fix the positive resist for dry development 120 on the etch target layer 110. The underlayer 115 may include, for example, hexamethyldisilazane (HMDS), a silane compound having a vinyl group (for example, vinyldisilazane, vinylchlorosilane, vinyloxysilane, etc.), a polymer having a vinyl group, or an organometallic oxide. According to some implementations, the underlayer 115 may be omitted.

The positive resist for dry development 120 includes tin oxide nanoclusters and a compound having Lewis basicity, and the tin oxide nanoclusters may include a core structure including tin oxide.

Forming the positive resist for dry development 120 may include applying a positive resist composition for dry development on the underlayer 115 or the etch target layer 110. Applying the positive resist composition for dry development on the underlayer 115 or the etch target layer 110 may be performed by, for example, a spin coating method. Forming the positive resist for dry development 120 may include performing PAB (post-apply baking) at a temperature of 50 degrees Celsius-150 degrees Celsius after applying the positive resist composition for dry development. The temperature at which PAB is performed may be, for example, 50 degrees Celsius-150 degrees Celsius, or 80 degrees Celsius-120 degrees Celsius.

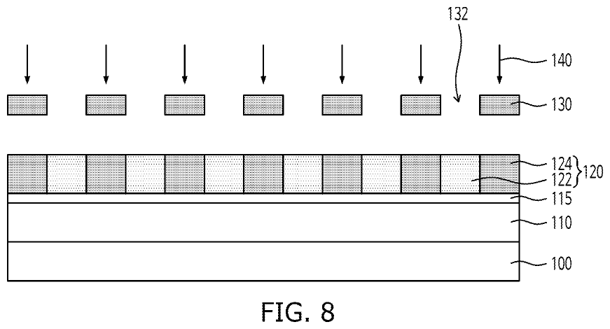

Referring to FIG. 8, the method for manufacturing a semiconductor device may include performing an exposure process on the positive resist for dry development 120 after forming the positive resist for dry development 120. The exposure process may include irradiating light 140 onto the positive resist for dry development 120. For example, the exposure process may include aligning a photomask 130 on the positive resist for dry development 120 and irradiating the light 140 onto the positive resist for dry development 120 through the photomask 130. In an implementation, the light 140 may be ultraviolet rays. For example, the ultraviolet rays may be extreme ultraviolet rays or deep ultraviolet rays. In another implementation, the exposure process may include irradiating and scanning the light 140 onto the positive resist for dry development 120 using an electron beam lithography apparatus. The light 140 may be, for example, an electron beam. The positive resist for dry development 120 may include an exposure region 122 exposed to the light 140 and a non-exposure region 124 not exposed to the light 140. For example, the light 140 may be irradiated to the exposure region 122 through an opening 132 of the photomask 130 and may be blocked by the photomask 130 so as not to be irradiated to the non-exposure region 124.

In the exposure region 122 of the positive resist for dry development 120, the organic ligand R may be detached from the pre-exposure tin oxide nanoclusters represented by Chemical Formula 1 by photons of the light 140. For example, the organic ligand is detached from the core structure of the tin oxide nanocluster represented by Chemical Formula 1 by electron beam or ultraviolet photons, and accordingly, the core structure of the tin oxide nanocluster may have Lewis acidity. The compound having Lewis basicity has a functional group that acts as a Lewis base, and the functional group that acts as a Lewis base may bond to a tin atom from which the organic ligand R is detached through an acid-base interaction. Accordingly, at least a portion of the tin oxide nanoclusters in the exposure region 122 may include the compound having Lewis basicity bonded to the core structure including tin oxide. For example, at least a portion of the tin oxide nanoclusters in the exposure region 122 may have a structure in which the organic ligand R is substituted with the functional group that acts as a Lewis base. The non-exposure region 124 of the positive resist for dry development 120 may include a mixture of the tin oxide nanoclusters before performing exposure represented by Chemical Formula 1 and the compound having Lewis basicity.

As the organic ligand R of the tin oxide nanoclusters before performing exposure represented by Chemical Formula 1 is substituted with the functional group that acts as a Lewis base in the exposure region 122 of the positive resist for dry development 120, aggregation between the tin oxide nanoclusters having Lewis acidity due to air exposure is suppressed, so that an etch contrast between the exposure region 122 and the non-exposure region 124 may increase in a later dry development process.

In an implementation, after performing the exposure process, treating the positive resist for dry development with an electron-donating ligand may be included. For example, treatment with the electron-donating ligand may be performed after performing the exposure process and before selectively removing the exposure region. The electron-donating ligand may bond to the core structure of the tin oxide nanocluster having Lewis acidity in the exposure region 122. Accordingly, at least a portion of the tin oxide nanoclusters in the exposure region 122 may include the electron-donating ligand bonded to the core structure including tin oxide. The electron-donating ligand bonds to the core structure having Lewis acidity to form a volatile metal compound, and accordingly, the etch contrast between the exposure region 122 and the non-exposure region 124 may be maximized.

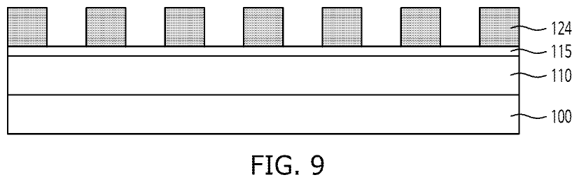

Referring to FIG. 9, after the exposure process, the photomask 130 may be removed. A dry development process may be performed on the exposed positive resist for dry development 120. Performing the dry development process may include removing the exposure region 122 of the positive resist for dry development 120 using a dry development gas. The dry development process is a method using a gas having high chemical reactivity, wherein collapse of the resist pattern occurring due to a capillary phenomenon caused by a developer used in a wet development process is suppressed, and accordingly, a positive resist pattern having an ultra-fine line width may be uniformly formed. As an example of the dry development gas, a mixed gas of O₂/CF₄ may be used, but is not limited thereto, and any dry development gas used in the relevant technical field may be used. By the dry development process, the exposure region 122 of the positive resist for dry development 120 may be selectively removed. The non-exposure region 124 of the positive resist for dry development 120 may be referred to as a photoresist pattern, and the photoresist pattern may be a positive pattern.

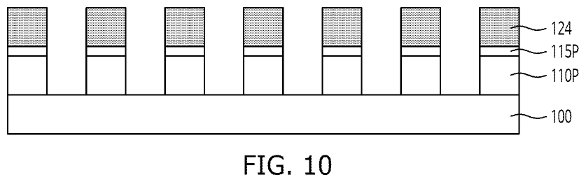

Referring to FIG. 10, the underlayer 115 and the etch target layer 110 may be etched using the photoresist pattern as an etch mask. Etching the underlayer 115 and the etch target layer 110 may include, for example, performing a wet or dry etching process. The underlayer 115 and the etch target layer 110 are etched to form an underlayer pattern 115P and a lower pattern 110P, respectively. After the lower pattern 110P is formed, the photoresist pattern may be removed. The lower pattern 110P may be a semiconductor pattern, a conductive pattern, or an insulating pattern in a semiconductor device.

A multilayered structure formed using the positive resist for dry development according to implementations of the present disclosure is described.

Referring again to FIG. 7, the multilayered structure may include the etch target layer 110 on the substrate 100 and the positive resist for dry development 120 on the etch target layer 110. According to some implementations, the multilayered structure may further include the underlayer 115 interposed between the etch target layer 110 and the positive resist for dry development 120.

Referring again to FIG. 8, the positive resist for dry development 120 may include the exposure region 122 exposed to the light 140 and the non-exposure region 124 not exposed to the light 140. At least a portion of the tin oxide nanoclusters in the exposure region 122 of the positive resist for dry development 120 may have a structure in which the organic ligand R of the tin oxide nanoclusters before performing the exposure process represented by Chemical Formula 1 is substituted with the functional group that acts as a Lewis base. The non-exposure region 124 of the positive resist for dry development 120 may include tin oxide nanoclusters having the same structure as the tin oxide nanoclusters before performing the exposure process represented by Chemical Formula 1.

As used herein, the term “at least one of” can refer to and encompass any and all possible combinations of one or more of the associated listed terms. For example, the term “at least one of A, B, or C” means that (i) at least one of A, (ii) at least one of B, (iii) at least one of C, (iv) at least one of A and at least one of B, (v) at least one of B and at least one of C, (vi) at least one of A and at least one of C, or (vi) at least one of A, at least one of B and at least one of C are possible, where A, B and C may be singular or plural.

While the present disclosure contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The above description of the implementations of the present disclosure provides examples for explaining the present disclosure. Therefore, the present disclosure is not limited to the above implementations, and it is obvious that many modifications and changes are possible, such as combining and implementing the above implementations by those having common knowledge in the relevant technical field within the technical spirit of the present disclosure.

What is claimed is:

1. A positive resist for dry development, the positive resist comprising:
tin oxide nanoclusters; and
a compound having Lewis basicity,
wherein the tin oxide nanoclusters comprise a core structure comprising tin oxide.

2. The positive resist of claim 1, wherein at least a portion of the tin oxide nanoclusters comprises organic ligands bonded to the core structure.

3. The positive resist of claim 2, wherein the organic ligands comprise alkyl groups having 1-20 carbon atoms bonded to a tin element in the core structure.

4. The positive resist of claim 1, wherein the compound having the Lewis basicity is bonded to the core structure.

5. The positive resist of claim 1, wherein at least a portion of the tin oxide nanoclusters comprises electron-donating ligands bonded to the core structure, and the electron-donating ligands comprise at least one of an amine-based ligand or an oxygen-based ligand.

6. The positive resist of claim 5, wherein the oxygen-based ligand comprises hexafluoroacetylacetone.

7. The positive resist of claim 1, wherein the compound having the Lewis basicity comprises at least one of a polymer or an organic small molecule, wherein each of the polymer and the organic small molecule comprises a functional group that acts as a Lewis base, and the functional group has a lone pair of electrons.

8. The positive resist of claim 7, wherein the functional group comprises at least one of a hydroxyl group, a phenol group, a thiol group, an amine group, a carboxylic acid group, an ester group, a carbonyl group, an amide group, a carbamate group, an urea group, a sulfoxy group, a sulfonyl group, a sulfone ester group, a cyanide group, or an isocyanide group.

9. The positive resist of claim 7, wherein the polymer comprises a repeating unit represented by Structural Formula 4 below: 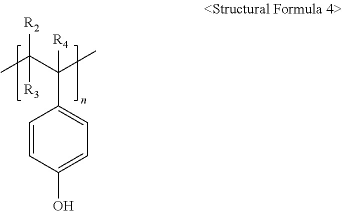
wherein, in the Structural Formula 4, R₂, R₃, and R₄ are each independently hydrogen, deuterium, or an alkyl group having 1-10 carbon atoms, and n is an integer in a range of from 1 to 1000.

10. The positive resist of claim 7, wherein the polymer comprises a copolymer represented by Structural Formula 5 below: 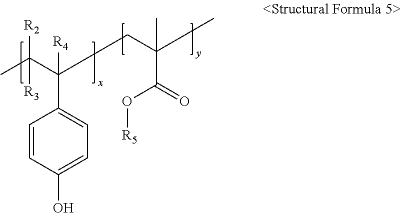
wherein, in the Structural Formula 5, R₂, R₃, and R₄ are each independently hydrogen, deuterium, or an alkyl group having 1-10 carbon atoms, R₅ is hydrogen, deuterium, an alkyl group having 1-10 carbon atoms, or a substituted or unsubstituted hydrocarbon ring having 3-30 carbon atoms, x is an integer in a range of from 1 to 1000, and y is an integer in a range of from 1 to 1000.

11. The positive resist of claim 7, wherein the organic small molecule comprises at least one of compounds represented by Structural Formula 6, Structural Formula 7, Structural Formula 8, or Structural Formula 9 below: 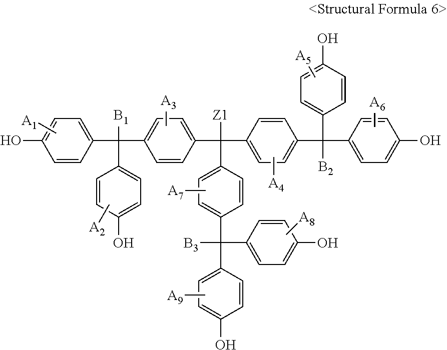
wherein, in the Structural Formula 6, A₁, A₂, A₃, A₄, A₅, A₆, A₇, A₈, and A₉ are each independently hydrogen, deuterium, or an alkyl group having 1-10 carbon atoms, B₁, B₂, and B₃ are each independently hydrogen, deuterium, or an alkyl group having 1-10 carbon atoms, and Z₁ is hydrogen, deuterium, an alkyl group having 1-10 carbon atoms, or a substituted or unsubstituted hydrocarbon ring having 3-30 carbon atoms; 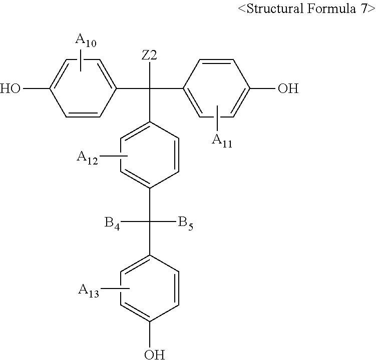
wherein, in the Structural Formula 7, A₁₀, A₁₁, A₁₂, and A₁₃ are each independently hydrogen, deuterium, or an alkyl group having 1-10 carbon atoms, B₄ and B₅ are each independently hydrogen, deuterium, or an alkyl group having 1-10 carbon atoms, and Z₂ is hydrogen, deuterium, an alkyl group having 1-10 carbon atoms, or a substituted or unsubstituted hydrocarbon ring having 3-30 carbon atoms; 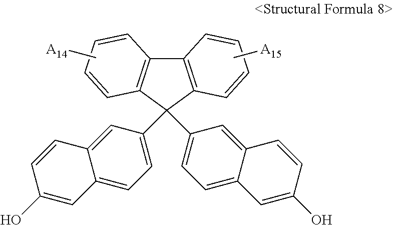
wherein, in the Structural Formula 8, A₁₄ and A₁₅ are each independently hydrogen, deuterium, an alkyl group having 1-10 carbon atoms, or a substituted or unsubstituted hydrocarbon ring having 3-30 carbon atoms; 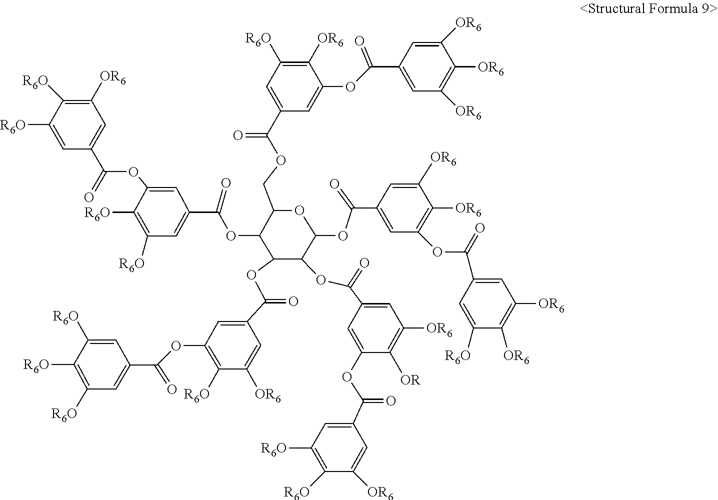
Wherein, in the Structural Formula 9, R₆ is represented by Structural Formula 10 below: 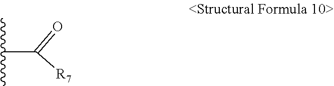
wherein, in the Structural Formula 10, R₇ is hydrogen, deuterium, an alkyl group having 1-10 carbon atoms, or a substituted or unsubstituted hydrocarbon ring having 3-30 carbon atoms.

12. The positive resist of claim 1, wherein the tin oxide nanoclusters comprise counter anions bonded to the core structure, and the counter anions comprise at least one of a sulfonate anion or a carboxylate anion.

13. A method for manufacturing a semiconductor device, the method comprising:
forming an etch target layer on a substrate;
forming a positive resist on the etch target layer;
performing an exposure process on the positive resist; and
performing a dry development process to selectively remove an exposure region of the positive resist,
wherein the positive resist comprises:
tin oxide nanoclusters; and
a compound having Lewis basicity,
wherein the tin oxide nanoclusters comprise a core structure comprising tin oxide.

14. The method of claim 13, wherein the positive resist comprises the exposure region exposed by the exposure process and a non-exposure region not exposed by the exposure process.

15. The method of claim 14, wherein the compound having the Lewis basicity is bonded to the core structure of the tin oxide nanoclusters in the exposure region.

16. The method of claim 14, comprising:
after performing the exposure process, treating the positive resist with an electron-donating ligand,
wherein the electron-donating ligand comprises at least one of an amine-based ligand or an oxygen-based ligand.

17. The method of claim 16, wherein at least a portion of the tin oxide nanoclusters in the exposure region comprise the electron-donating ligand bonded to the core structure.

18. The method of claim 14, wherein the tin oxide nanoclusters in the non-exposure region comprise organic ligands bonded to the core structure.

19. The method of claim 13, wherein the exposure process is performed using an electron beam or ultraviolet rays.

20. The method of claim 13, wherein forming the positive resist comprises:
applying a positive resist composition on the etch target layer; and
performing post-apply baking for the applied positive resist composition.
